(19) United States
(12) Patent Application Publication
(10) Pub. No.: US 2009/0231175 A1
(43) Pub. Date: Sep. 17, 2009

(54) MULTIMEDIA SIGNAL PROCESSING APPARATUS

(76) Inventors: Hua Wu, Hsinchu County (TW); Tzu-Shiun Liu, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/046,462

(22) Filed: Mar. 12, 2008

(51) Int. Cl. H03M 1/66

(52) U.S. Cl. 341/144

(57) ABSTRACT

A multimedia signal processing apparatus includes: a first digital-to-analog converter (DAC) for performing digital-to-analog conversion on a first set of digital values to generate a first set of analog signals, where the first set of digital values represents a first portion of an image to be displayed; a second DAC for performing digital-to-analog conversion on a second set of digital values to generate a second set of analog signals, where the second set of digital values represents a second portion of the image to be displayed; and a plurality of driver integrated circuits (ICs), coupled to the first and the second DACs, for driving according to the first and the second sets of analog signals, respectively.

### BACKGROUND

The present invention relates to driving liquid crystal displays (LCDs), and more particularly, to multimedia signal processing apparatuses having an LCD panel.

Regarding small-sized LCD panels, like a 7-inch LCD panel for example, the most common resolution of the day for analog panels is typically (480*234) pixels. Here, the term “analog panels” represents the LCD panels with analog source driver integrated circuits (ICs). That is, the internal process scheme of the driver ICs for driving sources of display units of the LCD panels is analog. If a higher resolution such as (800*480) pixels is required, digital panels are typically utilized for implementation according to the related art. Here, the term “digital panels” represents the LCD panels with digital source driver ICs. That is, the internal process scheme of the driver ICs for driving the sources of the display units of the LCD panels is digital.

According to the related art, utilizing digital source driver ICs may have benefits such as better noise-resistant capabilities while implementing a small-sized LCD panel with a higher resolution. However, utilizing digital source driver ICs leads to disadvantages such as a higher cost of driver ICs, and a large number of data connections between the small-sized LCD panel and a printed circuit board (PCB) of a control circuit (e.g. the PCB for mounting an LCD control ASIC). For example, the number of data connections required for each of red, green, and blue channels (which are typically referred to as R/G/B channels) is six, the overall number of data connections between the small-sized LCD panel and the PCB with digital source driver ICs is eighteen, while the number of data connections for implementing a small-sized LCD panel by utilizing analog source driver ICs is merely three. Referring to FIG. 1 illustrating a combination 100 of an LCD panel 110 and a control circuit 120 according to the related art, the LCD panel 110 is implemented by utilizing analog source driver ICs such as a set of LCD driver ICs (LDIs) 112-1, 112-2, . . . , and 112-6, and there are three data connections coupled between a digital-to-analog converter (DAC) 122 within the control circuit 120 and the first LDI 112-1 of the set of LDIs.

It is noted that no matter whether the internal process scheme of the source driver ICs is digital or analog, the source driver ICs typically drive the sources of the display units of the LCD panels by at least one analog driving voltage. As a result, utilizing digital source driver ICs may lead to another disadvantage such as requiring of a larger number of digital-to-analog converters (DACs) within the digital source driver ICs.

### SUMMARY

It is an objective of the claimed invention to provide multimedia signal processing apparatuses, so that a small-sized liquid crystal display (LCD) panel with a higher resolution can be implemented by utilizing analog source driver integrated circuits (ICs).

An exemplary embodiment of a multimedia signal processing apparatus comprises: a scalar for performing a scaling operation of an image; a formatter, coupled to the scalar, for generating a first set of digital values and a second set of digital values according to a scaling result of the scaling operation, where the first set of digital values represents a first portion of the image, and the second set of digital values represents a second portion of the image; a first digital-to-analog converter (DAC), coupled to the formatter, for performing digital-to-analog conversion on the first set of digital values to generate a first set of analog signals; a second DAC, coupled to the formatter, for performing digital-to-analog conversion on the second set of digital values to generate a second set of analog signals; a panel for displaying the image; and a plurality of driver ICs, coupled to the first and the second DACs and the panel, for driving the panel according to the first and the second sets of analog signals, respectively.

An exemplary embodiment of a multimedia signal processing apparatus comprises: a first DAC for performing digital-to-analog conversion on a first set of digital values to generate a first set of analog signals, where the first set of digital values represents a first portion of an image; a second DAC for performing digital-to-analog conversion on a second set of digital values to generate a second set of analog signals, where the second set of digital values represents a second portion of the image; an analog panel for displaying the image; and a plurality of driver ICs, coupled to the first and the second DACs and the analog panel, for driving the analog panel according to the first and the second sets of analog signals, respectively.

An exemplary embodiment of a multimedia signal processing apparatus comprises: a first DAC for performing digital-to-analog conversion on a first set of digital values to generate a first set of analog signals, where the first set of digital values represents a first portion of an image to be displayed; a second DAC for performing digital-to-analog conversion on a second set of digital values to generate a second set of analog signals, where the second set of digital values represents a second portion of the image to be displayed; and a plurality of driver ICs, coupled to the first and the second DACs, for receiving the first and the second sets of analog signals and driving according to the first and the second sets of analog signals, respectively.

An exemplary embodiment of a multimedia signal processing apparatus comprises: a first DAC for performing digital-to-analog conversion on a first set of digital values to generate a first set of analog signals, where the first set of digital values represents a first portion of an image; a second DAC for performing digital-to-analog conversion on a second set of digital values to generate a second set of analog signals, where the second set of digital values represents a second portion of the image; a panel for displaying the image; and a plurality of driver ICs, coupled to the first and the second DACs and the panel, for driving the panel according to the first and the second sets of analog signals, respectively.

An exemplary embodiment of a multimedia signal processing apparatus comprises: a first DAC for performing digital-to-analog conversion on a first set of digital values to generate a first set of analog signals, where the first set of digital values represents a first portion of an image to be displayed; a second DAC for performing digital-to-analog conversion on a second set of digital values to generate a second set of analog signals, where the second set of digital values represents a second portion of the image to be displayed; and a plurality of driver ICs, coupled to the first and the second DACs, for driving displaying of the image according to the first and the second sets of analog signals, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a liquid crystal display (LCD) panel and a control circuit according to the related art, where the LCD panel is implemented by utilizing analog source driver integrated circuits (ICs).

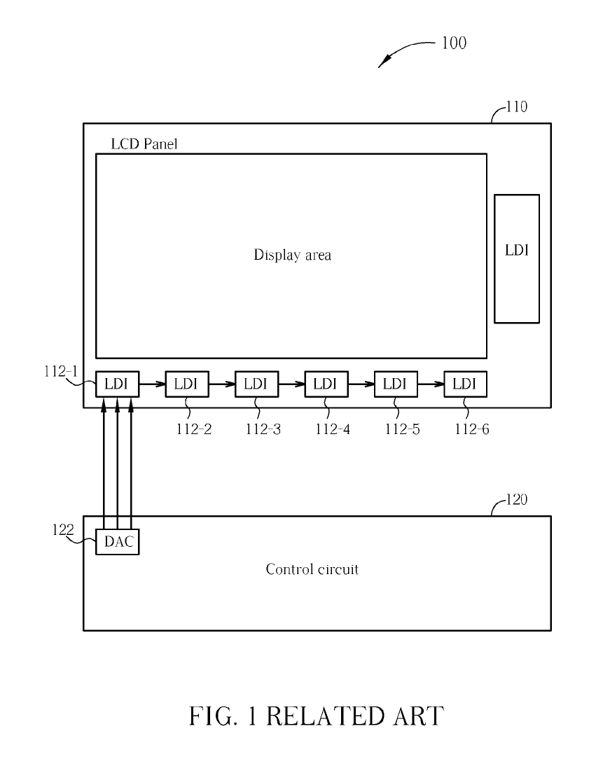

FIG. 2 is a diagram of a multimedia signal processing apparatus according to one embodiment of the present invention.

FIG. 3 is a diagram of the control circuit shown in FIG. 2.

FIG. 4 is a diagram of a multimedia signal processing apparatus according to another embodiment of the present invention.

FIG. 5 is a diagram of the control circuit shown in FIG. 4.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

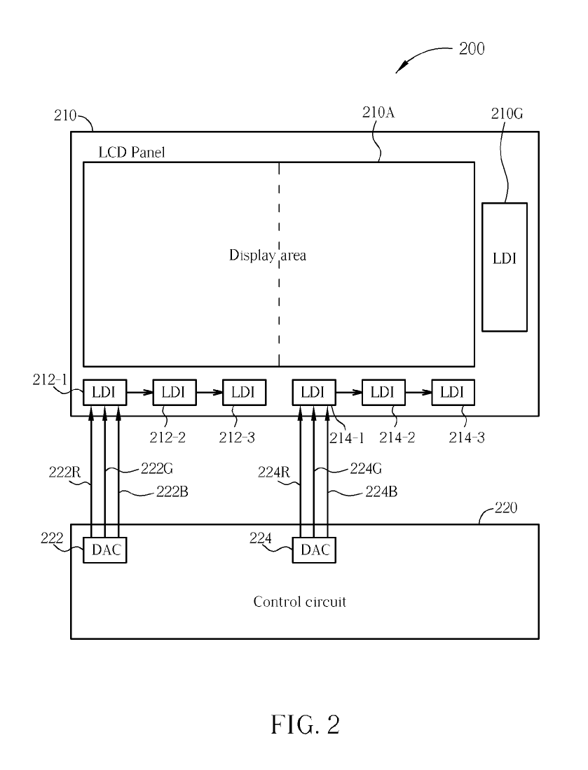

Please refer to FIG. 2. FIG. 2 is a diagram of a multimedia signal processing apparatus 200 according to a first embodiment of the present invention, where the multimedia signal processing apparatus 200 comprises a liquid crystal display (LCD) panel 210 and a control circuit 220. The multimedia signal processing apparatus 200 of this embodiment further comprises a plurality of driver integrated circuits (ICs) such as a first set of LCD driver ICs (LDIs) 212-1, 212-2, and 212-3, a second set of LDIs 214-1, 214-2, and 214-3, and another LDI 210G, where the driver ICs are positioned on or within the LCD panel 210, and are coupled to a plurality of display units (not shown) of the LCD panel 210. For example, the driver ICs can be attached to and/or mounted on the LCD panel 210.

In the first embodiment, an example of the multimedia signal processing apparatus 200 is a television (TV) receiver. Accordingly, the LCD panel 210 of this embodiment can be a small-sized LCD panel, for example, a 7-inch LCD panel whose resolution is (800*480) pixels, which means the number of the display units mentioned above is typically a multiple of (800*480). As shown in FIG. 2, the LCD panel 210 comprises a display area 210A for displaying an image, and the display area 210A represents the region where the display units described above are positioned. In addition, the two sets of LDIs of this embodiment are driver ICs for driving sources of these display units, and the LDI 210G of this embodiment is utilized for driving gates of these display units. Additionally, the internal process scheme of the two sets of LDIs mentioned above is analog, which means the LCD panel 210 of this embodiment is an analog panel.

According to this embodiment, the control circuit 220 comprises a plurality of digital-to-analog converters (DACs) 222 and 224, where there are three data connections coupled between the DAC 222 and the first LDI 212-1 of the first set of LDIs, and there are three data connections coupled between the DAC 224 and the first LDI 214-1 of the second set of LDIs. As shown in FIG. 2, the DAC 222 of this embodiment includes three output terminals 222R, 222G, and 222B respectively corresponding to red, green, and blue channels (which are typically referred to as R/G/B channels), and the DAC 224 of this embodiment includes three output terminals 224R, 224G, and 224B respectively corresponding to the red, green, and blue channels.

The control circuit 220 of this embodiment is capable of generating a first set of digital values representing a first portion of an image to be displayed, and is capable of generating a second set of digital values representing a second portion of the image to be displayed. For example, the first portion is a partial image displayed on the left half of the display area 210A, and the second portion is another partial image displayed on the right half of the display area 210A, where the left half and the right half of the display area 210A are seamless to a user viewing at a normal distance according to this embodiment.

The DAC 222 of this embodiment performs digital-to-analog conversion on the first set of digital values to generate a first set of analog signals, and outputs the first set of analog signals through the output terminals 222R, 222G, and 222B, so the first set of LDIs 212-1, 212-2, and 212-3 may receive the first set of analog signals, where the LDI 212-1 is coupled to the DAC 222 directly and the LDIs 212-2 and 212-3 are coupled to the DAC 222 indirectly, as shown in FIG. 2. In addition, the first set of LDIs 212-1, 212-2, and 212-3 drives the LCD panel 210 according to the first set of analog signals. More particularly in this embodiment, the first set of LDIs 212-1, 212-2, and 212-3 drives the display units corresponding to the left half of the display area 210A according to the first set of analog signals.

Similarly, the DAC 224 of this embodiment performs digital-to-analog conversion on the second set of digital values to generate a second set of analog signals, and outputs the second set of analog signals through the output terminals 224R, 224G, and 224B, so the second set of LDIs 214-1, 214-2, and 214-3 may receive the second set of analog signals, where the LDI 214-1 is coupled to the DAC 224 directly and the LDIs 214-2 and 214-3 are coupled to the DAC 224 indirectly, as shown in FIG. 2. In addition, the second set of LDIs 214-1, 214-2, and 214-3 drives the LCD panel 210 according to the second set of analog signals. More particularly in this embodiment, the second set of LDIs 214-1, 214-2, and 214-3 drives the display units corresponding to the right half of the display area 210A according to the second set of analog signals.

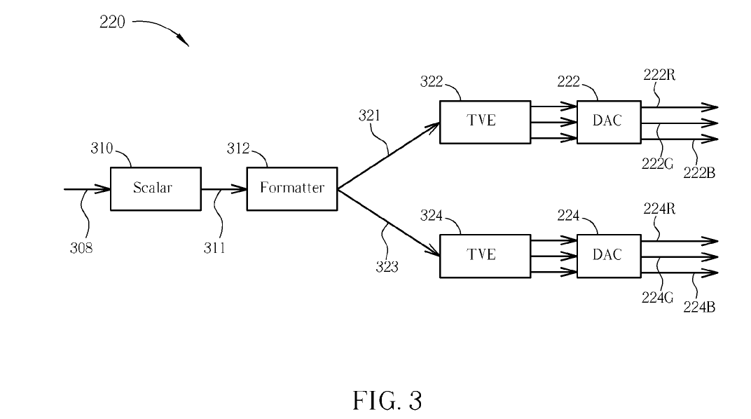

Please refer to FIG. 3. FIG. 3 is a diagram of the control circuit 220 shown in FIG. 2, where the control circuit 220 comprises a scalar 310, a formatter 312, and two TV encoders (TVEs) 322 and 324. The scalar 310 of this embodiment is capable of performing a scaling operation of an image according to the video data 308 thereof. Here, the video data 308 represents the source image data of the image to be displayed. The formatter 312 of this embodiment is capable of generating the first set of digital values and the second set of digital values according to a scaling result 311 of the scaling operation, where the first set of digital values can be output into the TVE 322 through an intermediate signal 321 according to a specific frame format, and the second set of digital values can be output into the TVE 324 through another intermediate signal 323 according to the specific frame format.

According to this embodiment, the formatter 312 outputs digital values corresponding to the partial image to be displayed on the left half of the display area 210A as the first set of digital values, and outputs digital values corresponding to the partial image to be displayed on the right half of the display area 210A as the second set of digital values. If the resolution of the whole image to be displayed on the display area 210A is (800*480) pixels as mentioned, the resolution of each of the partial images to be displayed on the left and right halves can be (400*480) pixels respectively.

As shown in FIG. 3, each of the TVEs 322 and 324 is a 3-channel TVE including three output terminals. The TVE 322 of this embodiment is capable of encoding the first set of digital values to output the first set of digital values through the three output terminals thereof according to a specific signal format. As a result, the DAC 222 performs digital-to-analog conversion on the first set of digital values from the TVE 322 to output the first set of analog signals through the output terminals 222R, 222G, and 222B. Similarly, the TVE 324 of this embodiment is capable of encoding the second set of digital values to output the second set of digital values through the three output terminals thereof according to the specific signal format. As a result, the DAC 224 performs digital-to-analog conversion on the second set of digital values from the TVE 324 to output the second set of analog signals through the output terminals 224R, 224G, and 224B.

In the first embodiment, an operation frequency of the DAC 222 is equal to an operation frequency of the DAC 224. According to a variation of the first embodiment, a left partial image and a right partial image to be respectively displayed on different portions of the display area 210A of the LCD panel 210 are not necessarily of the same resolution, so an operation frequency of the DAC 222 is not necessarily equal to an operation frequency of the DAC 224. For example, the resolution of the left partial image to be displayed is approximately twice as high as the resolution of the right partial image to be displayed, the coupling between the source driver ICs may be varied according to the resolutions of the left and right partial images. As a result, within the first set of LDIs of this variation, there are four LDIs that are coupled to the DAC 222 directly or indirectly, and within the second set of LDIs of this variation, there are two LDIs that are coupled to the DAC 224 directly or indirectly, where the operation frequency of the DAC 222 is approximately twice as high as the operation frequency of the DAC 224.

According to another variation of the first embodiment, the multimedia signal processing apparatus 200 can be a portable multimedia player supporting still image playback. According to another variation of the first embodiment, the multimedia signal processing apparatus 200 can be a cellular phone. Yet according to another variation of the first embodiment, the multimedia signal processing apparatus 200 can be a portable digital versatile disc (DVD) player, and the multimedia signal processing apparatus 200 further comprises a disc loader (not shown) for accessing an optical disc.

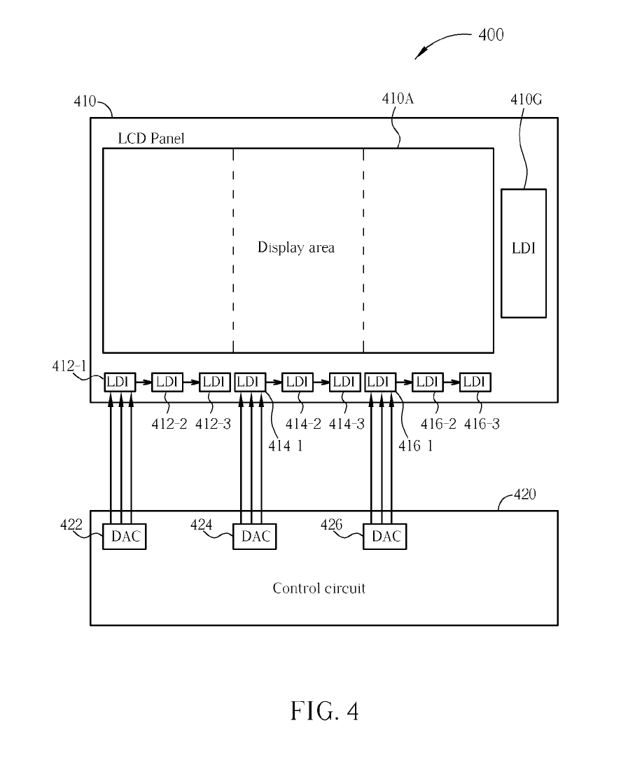

According to the first embodiment, the multimedia signal processing apparatus 200 drives displaying of the image according to the first and the second sets of analog signals, respectively. According to other embodiments of the present invention, the number of DACs respectively outputting different sets of analog signals to be received by corresponding sets of source driver ICs can be greater than two. Please refer to FIG. 4 illustrating a diagram of a multimedia signal processing apparatus 400 according to a second embodiment of the present invention, where the second embodiment is also a variation of the first embodiment. The differences between the first and the second embodiments are described as follows.

According to the second embodiment, the multimedia signal processing apparatus 400 comprises three sets of source driver ICs comprising a first set of LDIs 412-1, 412-2, and 412-3, a second set of LDIs 414-1, 414-2, and 414-3, and a third set of LDIs 416-1, 416-2, and 416-3. In this embodiment, the three sets of LDIs mentioned above drive sources of a plurality of display units corresponding to a left region, a central region, and a right region of a display area 410A of an LCD panel 410 of the multimedia signal processing apparatus 400 according to three sets of analog signals generated by three DACs 422, 424, and 426 of a control circuit 420 of the multimedia signal processing apparatus 400, respectively. For example, the resolution of an image to be displayed on the display area 410A is (1280*800) pixels, and the resolution of each of the left and central regions can be (427*800) pixels, and the resolution of the right region can be (426*800) pixels.

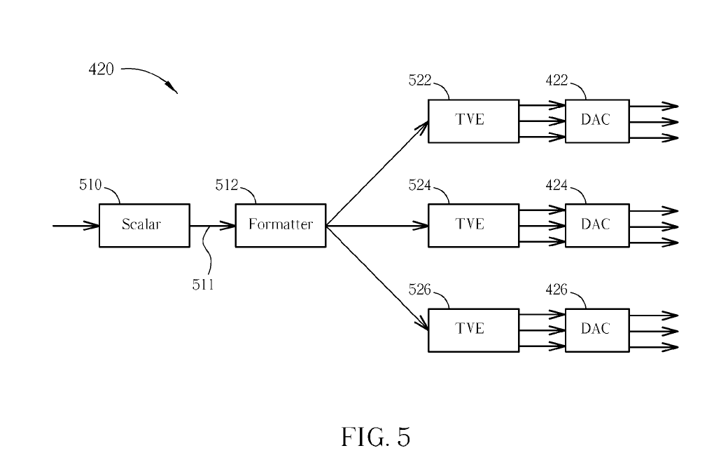

As shown in FIG. 5, a formatter 512 of the control circuit 420 of the second embodiment generates three sets of digital values according to a scaling result 511 of the scaling operation performed by a scalar 510 of the control circuit 420, and outputs digital values representing a left portion of the image to be displayed on the display area 410A (e.g. a left partial image to be displayed on the left region) as a first set of digital values, and outputs digital values representing a central portion of the image to be displayed on the display area 410A (e.g. a central partial image to be displayed on the central region) as a second set of digital values, and further outputs digital values representing a right portion of the image to be displayed on the display area 410A (e.g. a right partial image to be displayed on the right region) as a third set of digital values.

In addition, the control circuit 420 of this embodiment comprises three TVEs 522, 524, and 526 respectively encoding the first, second, and third sets of digital values from the formatter 512 to respectively output the first, second, and third sets of digital values into the DACs 422, 424, and 426 according to a specific signal format. As a result, the DACs 422, 424, and 426 perform digital-to-analog conversion on the first, second, and third sets of digital values to generate and output the first, second, and third sets of analog signals into the three sets of LDIs mentioned above, respectively.

In contrast to the related art, a small-sized LCD panel with a higher resolution can be implemented by utilizing analog source driver ICs according to the present invention. Therefore, the disadvantages of utilizing digital source driver ICs, for example, a higher cost of driver ICs, a large number of data connections between the small-sized LCD panel and a printed circuit board (PCB) of a control circuit, and a larger number of DACs within the digital source driver ICs, can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A multimedia signal processing apparatus comprising:
a scalar for performing a scaling operation of an image;
a formatter, coupled to the scalar, for generating a first set of digital values and a second set of digital values according to a scaling result of the scaling operation, wherein the first set of digital values represents a first portion of the image, and the second set of digital values represents a second portion of the image;
a first digital-to-analog converter (DAC), coupled to the formatter, for performing digital-to-analog conversion on the first set of digital values to generate a first set of analog signals;
a second DAC, coupled to the formatter, for performing digital-to-analog conversion on the second set of digital values to generate a second set of analog signals;
a panel for displaying the image; and
a plurality of driver integrated circuits (ICs), coupled to the first and the second DACs and the panel, for driving the panel according to the first and the second sets of analog signals, respectively.

2. The multimedia signal processing apparatus of claim 1, wherein the formatter further generates a third set of digital values according to the scaling result of the scaling operation, the third set of digital values represents a third portion of the image, and the multimedia signal processing apparatus further comprises:
a third DAC, coupled to the formatter, for performing digital-to-analog conversion on the third set of digital values to generate a third set of analog signals;
wherein the driver ICs are coupled to the first, the second, and the third DACs, and the driver ICs drive the panel according to the first, the second, and the third sets of analog signals, respectively.

3. The multimedia signal processing apparatus of claim 1, wherein each DAC includes three output terminals for outputting the corresponding set of analog signals generated by the DAC.

4. A multimedia signal processing apparatus comprising:
a first digital-to-analog converter (DAC) for performing digital-to-analog conversion on a first set of digital values to generate a first set of analog signals, wherein the first set of digital values represents a first portion of an image;
a second DAC for performing digital-to-analog conversion on a second set of digital values to generate a second set of analog signals, wherein the second set of digital values represents a second portion of the image;
an analog panel for displaying the image; and
a plurality of driver integrated circuits (ICs), coupled to the first and the second DACs and the analog panel, for driving the analog panel according to the first and the second sets of analog signals, respectively.

5. The multimedia signal processing apparatus of claim 4, further comprising:
a third DAC for performing digital-to-analog conversion on a third set of digital values to generate a third set of analog signals, wherein the third set of digital values represents a third portion of the image;
wherein the driver ICs are coupled to the first, the second, and the third DACs, and the driver ICs drive the analog panel according to the first, the second, and the third sets of analog signals, respectively.

6. The multimedia signal processing apparatus of claim 4, wherein each DAC includes three output terminals for outputting the corresponding set of analog signals generated by the DAC.

7. A multimedia signal processing apparatus comprising:
a first digital-to-analog converter (DAC) for performing digital-to-analog conversion on a first set of digital values to generate a first set of analog signals, wherein the first set of digital values represents a first portion of an image to be displayed;
a second DAC for performing digital-to-analog conversion on a second set of digital values to generate a second set of analog signals, wherein the second set of digital values represents a second portion of the image to be displayed; and
a plurality of driver integrated circuits (ICs), coupled to the first and the second DACs, for receiving the first and the second sets of analog signals and driving according to the first and the second sets of analog signals, respectively.

8. The multimedia signal processing apparatus of claim 7, wherein the driver ICs are positioned on or within a panel for displaying the image, and the driver ICs drive the panel according to the first and the second sets of analog signals, respectively.

9. A multimedia signal processing apparatus comprising:
a first digital-to-analog converter (DAC) for performing digital-to-analog conversion on a first set of digital values to generate a first set of analog signals, wherein the first set of digital values represents a first portion of an image;
a second DAC for performing digital-to-analog conversion on a second set of digital values to generate a second set of analog signals, wherein the second set of digital values represents a second portion of the image;
a panel for displaying the image; and
a plurality of driver integrated circuits (ICs), coupled to the first and the second DACs and the panel, for driving the panel according to the first and the second sets of analog signals, respectively.

10. The multimedia signal processing apparatus of claim 9, further comprising:
a third DAC for performing digital-to-analog conversion on a third set of digital values to generate a third set of analog signals, wherein the third set of digital values represents a third portion of the image;
wherein the driver ICs are coupled to the first, the second, and the third DACs, and the driver ICs drive the panel according to the first, the second, and the third sets of analog signals, respectively.

11. The multimedia signal processing apparatus of claim 9, wherein each DAC includes three output terminals for outputting the corresponding set of analog signals generated by the DAC.

12. The multimedia signal processing apparatus of claim 11, wherein the set of analog signals generated by the DAC correspond to red, green, and blue channels, respectively.

13. The multimedia signal processing apparatus of claim 9, wherein an operation frequency of the first DAC is equal to an operation frequency of the second DAC.

14. The multimedia signal processing apparatus of claim 9, wherein an operation frequency of the first DAC is not equal to an operation frequency of the second DAC.

15. The multimedia signal processing apparatus of claim 9, wherein the multimedia signal processing apparatus is a portable digital versatile disc (DVD) player, and the multimedia signal processing apparatus further comprises a disc loader for accessing an optical disc.

16. The multimedia signal processing apparatus of claim 9, wherein the multimedia signal processing apparatus is a cellular phone.

17. The multimedia signal processing apparatus of claim 9, wherein the multimedia signal processing apparatus is a portable multimedia player supporting still image playback.

18. The multimedia signal processing apparatus of claim 9, wherein the multimedia signal processing apparatus is a television (TV) receiver.

19. A multimedia signal processing apparatus comprising:
a first digital-to-analog converter (DAC) for performing digital-to-analog conversion on a first set of digital values to generate a first set of analog signals, wherein the first set of digital values represents a first portion of an image to be displayed;
a second DAC for performing digital-to-analog conversion on a second set of digital values to generate a second set of analog signals, wherein the second set of digital values represents a second portion of the image to be displayed; and
a plurality of driver integrated circuits (ICs), coupled to the first and the second DACs, for driving displaying of the image according to the first and the second sets of analog signals, respectively.

20. The multimedia signal processing apparatus of claim 19, wherein the driver ICs are positioned on or within a panel for displaying the image, and the driver ICs drive the panel according to the first and the second sets of analog signals, respectively.
